(19) United States
(12) Patent Application Publication
(10) Pub. No.: US 2017/0171963 A1
(43) Pub. Date: Jun. 15, 2017

(54) CONDUCTIVE HEAT SINK-WELDED PCB APPARATUS, CONDUCTIVE HEAT SINK AND WELDING METHOD THEREOF

(71) Applicants: Le Holdings (Beijing) Co., Ltd., Beijing (CN); LE SHI ZHI XIN ELECTRONIC TECHNOLOGY (TIANJIN) LIMITED

(72) Inventor: Xiaoming HOU, Tianjin (CN)

(21) Appl. No.: 15/250,524

(22) Filed: Aug. 29, 2016

Related U.S. Application Data
(63) Continuation of application No. PCT/CN2016/088669, filed on Jul. 5, 2016.

(30) Foreign Application Priority Data
Dec. 9, 2015 (CN) 201510920366.5

(51) Int. Cl. H05K 1/02; H05K 3/00; H05K 1/18; H05K 1/09

(52) U.S. Cl. CPC H05K 1/0259; H05K 1/0203; H05K 1/09; H05K 3/0061; H05K 1/181; H05K 2201/066

(57) ABSTRACT

A conductive heat sink-welded PCB apparatus, a conductive heat sink, and a welding method thereof is provided. The conductive heat sink-welded PCB apparatus includes: a PCB, provided for welding an IC device, and having a surface GND provided for welding; at least one piece of conductive foam, with one end being welded to the surface GND of the PCB and the other end being welded to a conductive heat sink; and the conductive heat sink, connected to the surface GND of the PCB through the conductive foam, for releasing ESD energy between the conductive heat sink and the PCB. In the present disclosure, the ESD energy between the conductive heat sink and the PCB can be released through the conductive foam, thereby avoiding damages to the IC device.

### CROSS REFERENCE TO RELATED APPLICATIONS

This application is a continuation of International Application No. PCT/CN2016/088669 filed on Jul. 5, 2016, which is based upon and claims priority to Chinese Patent Application No. 2015109203665, filed before Chinese Patent Office on Dec. 9, 2015 and entitled “CONDUCTIVE HEAT SINK-WELDED PCB APPARATUS, CONDUCTIVE HEAT SINK, AND WELDING METHOD THEREOF”, the entire contents of which are incorporated herein by reference.

### TECHNICAL FIELD

The present disclosure relates to the technical field of printed circuit board (PCB) welding, and more particularly, to a conductive heat sink-welded PCB apparatus, a conductive heat sink, and a welding method thereof

### BACKGROUND

With the development of integrated circuit (IC) industry since emergence, the IC integration level is increasing higher, and the design difficulty of anti-electrostatic discharge (ESD) capability of an IC grows. In the process of productization, an increasing number of products fail in ESD test, resulting in problems such as IC damages or system anomalies.

Referring to FIG. 1, normally an IC produces a large amount of heat in working, and a heat dissipation apparatus needs to be added; however, only an IC device 13 is provided between a conductive heat sink 11 and a PCB 12 in the related art. Therefore, during ESD experiment, because instantaneous charges may be coupled to the conductive heat sink 11, a large capacitor is formed for energy accumulation between the conductive heat sink 11 and the surface of the PCB 12 (embedded with a copper layer). During the implementation of the present disclosure, the inventor finds at least the following problem in the related art. If the contact between the conductive heat sink 11 and the PCB 12 is not good enough, the ESD energy can only be released through the IC device 13, so that the IC device 13 may endure high voltage impact, resulting in IC damages or internal program anomalies.

Therefore, it is a technical problem to be solved urgently in the related art on how to weld a conductive heat sink on a PCB.

### SUMMARY

In view of the above, the present disclosure provides a conductive heat sink-welded PCB apparatus, a conductive heat sink, and a welding method thereof, in which ESD energy between a conductive heat sink and a PCB can be released through conductive foam, thereby avoiding damages to an IC device.

In a first aspect, an embodiment of the present disclosure provides a conductive heat sink-welded PCB apparatus, including:
a PCB, provided for welding an IC device, and having a surface wire grounding terminal (Ground, GND) provided for welding;
at least one piece of conductive foam, with one end being welded to the surface GND of the PCB and the other end being welded to a conductive heat sink; and
the conductive heat sink, connected to the surface GND of the PCB through the conductive foam, for releasing ESD energy between the conductive heat sink and the PCB.

In a second aspect, an embodiment of the present disclosure further provides a method for welding a conductive heat sink, which is applied in an integrated circuit and includes:
welding the conductive heat sink to one end of at least one piece of conductive foam, welding the other end of the at least one piece of conductive foam to a surface GND of a PCB, and releasing ESD energy between the conductive heat sink and the PCB through the conductive foam.

### BRIEF DESCRIPTION OF THE DRAWINGS

One or more embodiments are illustrated by way of example, and not by limitation, in the figures of the accompanying drawings, wherein elements having the same reference numeral designations represent like elements throughout. The drawings are not to scale, unless otherwise disclosed.

FIG. 1 is a schematic structural diagram illustrating a conductive heat sink-welded PCB apparatus in the related art:

FIG. 2 is a schematic structural diagram illustrating a conductive heat sink-welded PCB apparatus in the present disclosure;

FIG. 3 is a schematic diagram illustrating welding of a conductive heat sink in the present disclosure;

FIG. 4 is a flowchart of a method for welding a conductive heat sink in the present disclosure; and

FIG. 5 is a schematic structural diagram illustrating a specific disclosure of a conductive heat sink-welded PCB in the present disclosure.

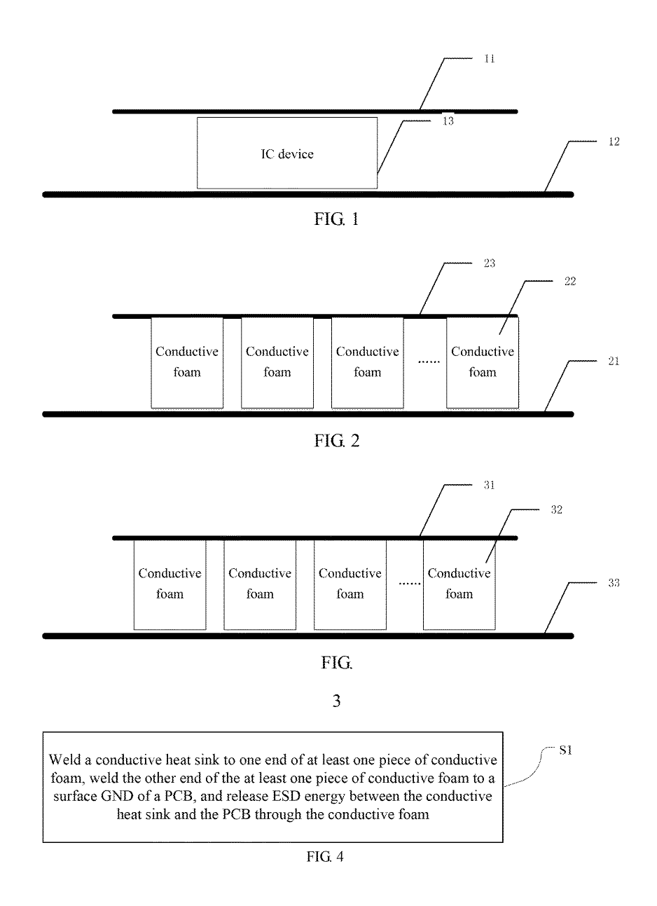

### DETAILED DESCRIPTION

In the present disclosure, a conductive heat sink is welded to one end of at least one piece of conductive foam, the other end of the at least one piece of conductive foam is welded to a surface GND of a PCB, and ESD energy between the conductive heat sink and the PCB is released through the conductive foam. The present disclosure adds an ESD energy release path, thereby achieving an IC protection effect and avoiding damages to an IC device.

Definitely, the implementation of any technical solution of the present disclosure does not need to achieve all the above advantages.

To make a person skilled in the art better understand the technical solutions of the present disclosure, the technical solutions in the embodiments of the present disclosure are described clearly and completely with reference to the accompanying drawings in the embodiments of the present disclosure. Apparently, the described embodiments are merely some of rather than all of the embodiments of the present disclosure. Based on the embodiments of the present disclosure, all other embodiments derived by a person of ordinary skill in the art shall fall within the protection scope of the present disclosure.

The specific implementation of the present disclosure is described in detail below with reference to the accompanying drawings of the present disclosure.

Referring to FIG. 2, a specific embodiment of the present disclosure provides a conductive heat sink-welded PCB apparatus, including:
a PCB 21, provided for welding an IC device, and having a surface GND provided for welding;
at least one piece of conductive foam 22, with one end being welded to the surface GND of the PCB 21 and the other end being welded to a conductive heat sink 23; and
the conductive heat sink 23, connected to the surface GND of the PCB 21 through the conductive foam 22, for releasing ESD energy between the conductive heat sink 23 and the PCB 21.

The present disclosure adds an ESD energy release path, thereby achieving an IC protection effect and avoiding damages to an IC device.

The conductive foam in the present disclosure is SMT conductive foam for it can be directly used for welding.

Normally an IC produces a large amount of heat in working, and a heat dissipation apparatus needs to be added. The conductive heat sink in the present disclosure is an aluminum conductive heat sink because an aluminum heat sink has good heat conductivity and heat dissipation coefficients and a low cost and is convenient for welding.

A PCB, short for printed circuit board, is a provider of electrical connections of electronic components. The surface of a PCB is generally provided with a solder resistant/solder mask, and the copper side does not need to be entirely soldered with other parts, such that a layer of material (generally epoxy resin) is coated on non-soldered areas to isolate the copper layer from being soldered, which prevents short circuits between non-soldered lines. Green solder mask, red solder mask and blue solder mask are used in different processes. The surface GND of the PCB in the present disclosure is an embedded copper layer, that is, multiple copper layer areas not provided with a solder resistant/solder mask are maintained on the PCB, and the copper layer areas are of a ground potential.

In the present disclosure, the conductive heat sink is connected to a copper layer area (surface GND) of the PCB through at least one piece of conductive foam, such that an ESD energy release path is added. thereby achieving an IC protection effect and avoiding damages to an IC device.

Another embodiment of the present disclosure further provides a conductive heat sink. Referring to FIG. 3, the conductive heat sink 31 is welded to one end of at least one piece of conductive foam 32, the other end of the at least one piece of conductive foam is welded to a surface GND of a PCB 33, and ESD energy between the conductive heat sink 31 and the PCB 33 is released through the conductive foam 32.

The present disclosure adds an ESD energy release path. thereby achieving an IC protection effect and avoiding damages to an IC device.

The conductive foam in the present disclosure is SMT conductive foam for it can be directly used for welding.

Normally an IC produces a large amount of heat in working, and a heat dissipation apparatus needs to be added. The conductive heat sink in the present disclosure is an aluminum conductive heat sink because an aluminum heat sink has good heat conductivity and heat dissipation coefficients and a low cost and is convenient for welding.

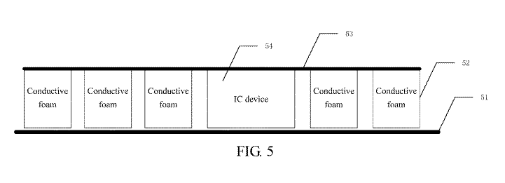

Still another embodiment of the present disclosure further provides a method for welding a conductive heat sink. Referring to FIG. 4, the method includes:

S1: A conductive heat sink is welded to one end of at least one piece of conductive foam, the other end of the at least one piece of conductive foam is welded to a surface GND of a PCB, and ESD energy between the conductive heat sink and the PCB is released through the conductive foam.

The present disclosure adds an ESD energy release path. thereby achieving an IC protection effect and avoiding damages to an IC device.

The conductive foam in the present disclosure is SMT conductive foam for it can be directly used for welding.

Normally an IC produces a large amount of heat in working, and a heat dissipation apparatus needs to be added. The conductive heat sink in the present disclosure is an aluminum conductive heat sink because an aluminum heat sink has good heat conductivity and heat dissipation coefficients and a low cost and is convenient for welding.

A PCB, short for printed circuit board, is a provider of electrical connections of electronic components. The surface of a PCB is generally provided with a solder resistant/solder mask, and the copper side does not need to be entirely soldered with other parts, such that a layer of material (generally epoxy resin) is coated on non-soldered areas to isolate the copper layer from being soldered, which prevents short circuits between non-soldered lines. Green solder mask, red solder mask and blue solder mask are used in different processes. The surface GND of the PCB in the present disclosure is an embedded copper layer, that is, multiple copper layer areas not provided with a solder resistant/solder mask are maintained on the PCB, and the copper layer areas are of a ground potential.

In the present disclosure, the conductive heat sink is connected to a copper layer area (surface GND) of the PCB through at least one piece of conductive foam, such that an ESD energy release path is added, thereby achieving an IC protection effect and avoiding damages to an IC device.

The implementation of the present disclosure is illustrated in detail below through a specific disclosure scenario.

FIG. 5 illustrates a PCB 51 welded with an IC device. A surface GND of the PCB 51 is an embedded copper layer, that is, multiple copper layer areas not provided with a solder resistant/solder mask are maintained on the PCB 51, and the copper layer areas are of a ground potential.

Five pieces of SMT conductive foam 52 each have one end being welded to a copper layer area on the surface of the PCB 51 and the other end being welded to a conductive heat sink 53.

The aluminum conductive heat sink 53 is connected to the copper layer areas on the surface of the PCB 51 through the conductive foam 52, for releasing ESD energy between the conductive heat sink 53 and the PCB 51.

In the present disclosure, the ESD energy between the conductive heat sink 53 and the PCB 51 is not released only through an IC device 54, and the five pieces of conductive foam 52 are added to serve as ESD energy release paths, thereby achieving an effect of protecting the IC device 54 and avoiding damages to the IC device 54.

Although the embodiments of the present disclosure are described above. once knowing the basic creative concept, a person skilled in the art can make other modifications and variations to these embodiments. Therefore, the appended claims are intended to be construed as covering the embodiments and all the modifications and variations falling within the scope of the present disclosure. Obviously, a person skilled in the art can make various modifications and variations to the present disclosure without departing from the spirit and scope of the present disclosure. In this way, the present disclosure is intended to cover the modifications and variations if they fall within the scope of the appended claims of the present disclosure and equivalent technologies thereof.

What is claimed is:

1. A conductive heat sink-welded PCB apparatus, comprising:
a PCB, provided for welding an IC device, and having a surface GND provided for welding;
at least one piece of conductive foam, with one end being welded to the surface GND of the PCB and the other end being welded to a conductive heat sink; and
the conductive heat sink, connected to the surface GND of the PCB through the conductive foam, for releasing ESD energy between the conductive heat sink and the PCB.

2. The PCB apparatus according to claim 1, wherein the conductive foam is SMT conductive foam.

3. The PCB apparatus according to claim 1, wherein the conductive heat sink is an aluminum conductive heat sink.

4. The PCB apparatus according to claim I, wherein the surface GND of the PCB is an embedded copper layer.

5. A conductive heat sink. wherein the conductive heat sink is welded to one end of at least one piece of conductive foam, the other end of the at least one piece of conductive foam is welded to a surface GND of a PCB, and ESD energy between the conductive heat sink and the PCB is released through the conductive foam.

6. The conductive heat sink according to claim 5, wherein the conductive foam is SMT conductive foam.

7. The conductive heat sink according to claim 5, wherein the conductive heat sink is an aluminum conductive heat sink.

8. A method for welding a conductive heat sink, applied in an integrated circuit, and comprising:
welding the conductive heat sink to one end of at least one piece of conductive foam, welding the other end of the at least one piece of conductive foam to a surface GND of a PCB, and releasing ESD energy between the conductive heat sink and the PCB through the conductive foam.

9. The method according to claim 8, wherein the conductive foam is SMT conductive foam.

10. The method according to claim 8, wherein the conductive heat sink is an aluminum conductive heat sink.

11. The method according to claim 8, wherein the surface GND of the PCB is an embedded copper layer.
